(19) United States
(12) Patent Application Publication
(10) Pub. No.: US 2024/0387725 A1
(43) Pub. Date: Nov. 21, 2024

(54) SILICON CARBIDE SEMICONDUCTOR DEVICE

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 18/790,357

(22) Filed: Jul. 31, 2024

Related U.S. Application Data
(63) Continuation of application No. PCT/JP2023/023686, filed on Jun. 26, 2023.

(30) Foreign Application Priority Data
Aug. 19, 2022 (JP) 2022-131372

(51) Int. Cl. H01L 29/78; H01L 29/06; H01L 29/16; H01L 29/167

(52) U.S. Cl. CPC H01L 29/7813; H01L 29/0684; H01L 29/1608; H01L 29/167

(57) ABSTRACT

A silicon carbide semiconductor device, including: a semiconductor substrate; a first semiconductor region, a second semiconductor region and a third semiconductor region provided in the semiconductor substrate; a first trench penetrating through the third semiconductor region and the second semiconductor region in a depth direction and terminating in the first semiconductor region; a gate electrode provided in the first trench, via a gate insulating film; a plurality of second trenches penetrating through the third semiconductor region in the depth direction and terminating in the second semiconductor region; a fourth semiconductor region provided opposing, in the depth direction, a portion of the second semiconductor region that is below a bottom of each of the plurality of second trenches; and a first electrode and a second electrode provided at two main surfaces of the semiconductor substrate.

### CROSS REFERENCE TO RELATED APPLICATIONS

This is a continuation application of International Application PCT/JP2023/023686 filed on Jun. 26, 2023 which claims priority from a Japanese Patent Application No. 2022-131372 filed on Aug. 19, 2022, the contents of which are incorporated herein by reference.

### BACKGROUND OF THE INVENTION

### 1. Field of the Invention

Embodiments of the invention relate to a silicon carbide semiconductor device.

### 2. Description of the Related Art

A source trench structure having a gate trench embedded with a gate electrode and a source trench embedded with a source electrode as a double trench is a conventionally known trench gate SiC-MOSFET (metal oxide semiconductor field effect transistor having a metal-oxide-semiconductor three-layer structure) in which silicon carbide (SiC) is used as a semiconductor material.

The structure of a conventional silicon carbide semiconductor device is described. FIG. 9 is a cross-sectional view depicting the structure of the conventional silicon carbide semiconductor device. A conventional silicon carbide semiconductor device 110 depicted in FIG. 9 is a trench gate SiC-MOSFET with a source trench structure having a semiconductor substrate 130 containing silicon carbide, and source trenches 111 provided in the semiconductor substrate 130, at a front surface (a main surface constituted by a surface of an epitaxial layer 132) of the semiconductor substrate 130. In the semiconductor substrate 130, the epitaxial layer 132 of an n-type is formed by epitaxy on an n⁺-type starting substrate 131 containing silicon carbide, the epitaxial layer 132 constituting an n⁻-type drift region 102. The n⁺-type starting substrate 131 constitutes an n⁺-type drain region 101. In the epitaxial layer 132, a region excluding diffused regions (a p-type base region 103, n⁺-type source regions 105, and p⁺⁺-type contact regions 106) formed by ion implantation in the epitaxial layer 132 constitutes the n-type drift region 102. In the semiconductor substrate 130, at the front surface thereof, a trench gate structure is configured by the p-type base region 103, the n⁺-type source regions 105, the p⁺⁺-type contact regions 106, gate trenches 107, gate insulating films 108, and gate electrodes 109.

The gate trenches 107 and the source trenches 111 are provided alternating with one another repeatedly in a first direction X parallel to the front surface of the semiconductor substrate 130. A unit cell (functional unit of a device) includes one of the gate trenches 107 and a half of each of the source trenches 111 adjacent to the one of the gate trenches 107. The gate trenches 107 penetrate through the n⁺-type source regions 105 and the p-type base region 103 in a depth direction Z from the front surface of the semiconductor substrate 130 and terminate in the n-type drift region 102. In the gate trenches 107, the gate electrodes 109 are provided on the gate insulating films 108.

The source trenches 111 penetrate through the n⁺-type source regions 105 in the depth direction Z from the front surface of the semiconductor substrate 130. A depth of the source trenches 111 is at least equal to a depth of the gate trenches 107. One of the unit cells is configured by a portion between centers of any adjacent two of the source trenches 111 in the first direction X. In the source trenches 111, a source electrode 113 is embedded. Between the n⁻-type drift region 102 and the source trenches 111, the p-type base region 103 extends along inner walls of the source trenches 111.

Portions (hereinafter, p-type deep base portions) 104 of the p-type base region 103 along bottoms of the source trenches 111 form pn junctions with the n-type drift region 102 at deep positions closer to the n⁺-type drain region 101 than are bottoms of the gate trenches 107. In the source trench structure, the p-type deep base portions 104 at the bottoms of the source trenches 111 have a function of mitigating electric field applied to the gate insulating films 108 at the bottoms of the gate trenches 107. Thus, p-type regions are not disposed at positions facing the bottoms of the gate trenches 107.

No p-type regions are disposed at positions facing the bottoms of the gate trenches 107, whereby a width of a junction FET (JFET) portion increases, thereby greatly reducing JFET resistance, whereby on-resistance is reduced. The JFET portion is a portion of the n⁺-type drift region 102 adjacent to a channel (n-type inversion layer) formed in a portion of the p-type base region 103 along the gate trenches 107 when the SiC-MOSFET is on, the portion forms a current path of a main current (drift current) that passes through the channel.

The source trenches 111 are exposed in contact holes 112a of an interlayer insulating film 112. The source electrode 113, via the contact holes 112a of the interlayer insulating film 112, is embedded in the source trenches 111 and is in contact with the p-type base region 103, the n⁺-type source regions 105, and the p⁺⁺-type contact regions 106, at inner walls of the source trenches 111. A drain electrode 114 is provided in an entire area of a back surface (main surface constituted by a surface of the n⁺-type starting substrate 131) of the semiconductor substrate 130 and is electrically connected to the n⁺-type drain region 101.

As for a trench gate SiC-MOSFET with a conventional source trench structure, a device has been proposed in which a source insulating film is provided between a source electrode embedded in a source trench and a p-type base region at a bottom of the source trench, whereby the device suppresses an occurrence of punch-through (for example, refer to Japanese Laid-Open Patent Publication No. 2019-161200). In Japanese Laid-Open Patent Publication No. 2019-161200, a bottom of the gate trench and the p-type source region at the bottom of the source trench are surrounded by an n-type region provided in an entire area between the p-type base region and an n-type drift region.

As for a trench gate SiC-MOSFET with a conventional single trench structure having only a gate trench, a device has been proposed in which a p⁺-type region is disposed at a position facing a bottom of a gate trench and is disposed between adjacent gate trenches (for example, refer to Japanese Patent No. 6617657). In Japanese Patent No. 6617657, an n-type region is provided only directly beneath the p⁺-type region (side thereof facing an n⁺-type drain) between the adjacent gate trenches and an avalanche breakdown point is set to be directly beneath the p⁺-type region, whereby an occurrence of avalanche breakdown at the bottom of the gate trench is suppressed.

As for a trench gate silicon (Si)-MOSFET having a conventional source trench structure, a device has been proposed in which an n-type region is provided directly beneath a p⁺-type region at a bottom of a source trench, whereby an avalanche breakdown point is set to be directly beneath a bottom of the source trench, which has a depth shallower than a depth of a gate trench (for example, refer to Japanese Laid-Open Patent Publication No. 2005-057049). In Japanese Laid-Open Patent Publication No. 2005-057049, a p-type region is provided between the p⁺-type region at the bottom of the source trench and the n-type region and the cell pitch is reduced, whereby reduced on-resistance is realized for a low voltage class of 100V or less in which channel resistance is predominate.

### SUMMARY OF THE INVENTION

According to an embodiment of the present invention, a silicon carbide semiconductor device includes: a semiconductor substrate containing silicon carbide, the semiconductor substrate having a first main surface and a second main surface opposite to each other; a first semiconductor region of a first conductivity type, provided in the semiconductor substrate; a second semiconductor region of a second conductivity type, provided in the semiconductor substrate between the first main surface of the semiconductor substrate and the first semiconductor region; a third semiconductor region of the first conductivity type, selectively provided in the semiconductor substrate between the first main surface of the semiconductor substrate and the second semiconductor region; a first trench penetrating through the third semiconductor region and the second semiconductor region in a depth direction and terminating in the first semiconductor region; a gate electrode provided in the first trench, via a gate insulating film; a plurality of second trenches penetrating through the third semiconductor region in the depth direction and terminating in the second semiconductor region, at a depth at least equal to a depth of the first trench, the plurality of second trenches being provided apart from the first trench and a periphery of each of the plurality of second trenches being bordered by the second semiconductor region in a plan view of the silicon carbide semiconductor device; a fourth semiconductor region of the first conductivity type, provided opposing, in the depth direction, a portion of the second semiconductor region that is below a bottom of each of the plurality of second trenches, the fourth semiconductor region having a doping concentration higher than a doping concentration of the first semiconductor region; a first electrode provided at the first main surface of the semiconductor substrate, embedded in the plurality of second trenches, the first electrode being in contact with the second semiconductor region and the third semiconductor region at an inner wall of each of the plurality of second trenches; and a second electrode provided at the second main surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a silicon carbide semiconductor device according to a first embodiment is viewed from a front side of a semiconductor substrate.

FIG. 2 is a cross-sectional view depicting a structure along cutting line A-A′ in FIG. 1.

FIG. 3 is a cross-sectional view depicting the structure along cutting line B-B′ in FIG. 1.

FIG. 4 is a cross-sectional view depicting the structure along cutting line C-C′ in FIG. 1.

FIG. 5 is a cross-sectional view depicting the structure along cutting line D-D′ in FIG. 1.

FIG. 6 is a cross-sectional view depicting a structure of a silicon carbide semiconductor device according to a second embodiment.

FIG. 7 is a cross-sectional view depicting a structure of a silicon carbide semiconductor device according to a third embodiment.

FIG. 8 is a cross-sectional view of a structure of a silicon carbide semiconductor device according to the fourth embodiment.

FIG. 9 is a cross-sectional view depicting a structure of a conventional silicon carbide semiconductor device.

### DETAILED DESCRIPTION OF THE INVENTION

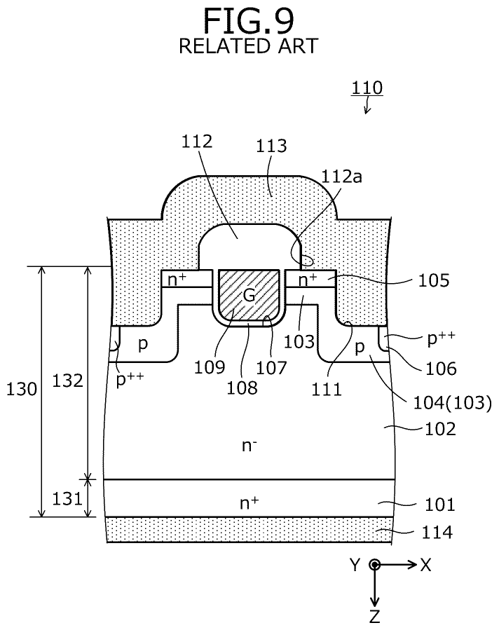

First problems associated with the conventional techniques are discussed. In the silicon carbide semiconductor device 110 (refer to FIG. 9), to mitigate electric field near the bottoms of the gate trenches 107 by the p-type deep base portions 104 at the bottoms of the source trenches 111, the gate trenches 107 and the source trenches 111 have to be disposed in proximity to one another. Thus, while JFET resistance may be relatively decreased by not disposing a p-type region at positions facing the bottoms of the gate trenches 107, the JFET resistance increases as compared to an instance in which the p-type deep base portions 104 are not disposed at the bottoms of the source trenches 111.

Embodiments of a silicon carbide semiconductor device according to the present invention are described in detain with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

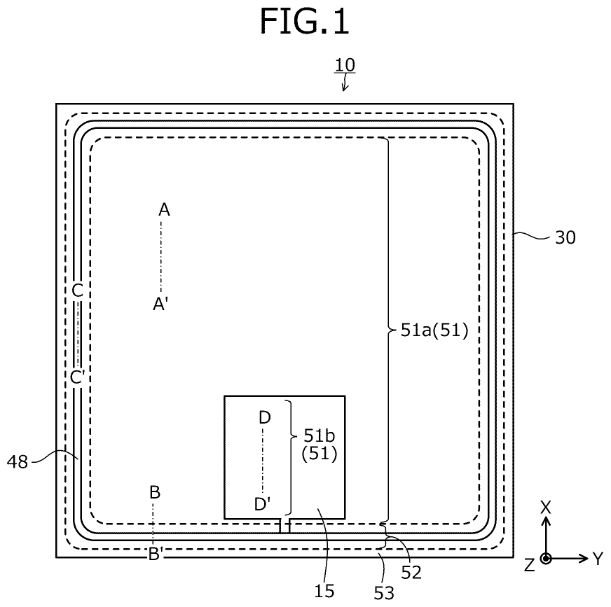

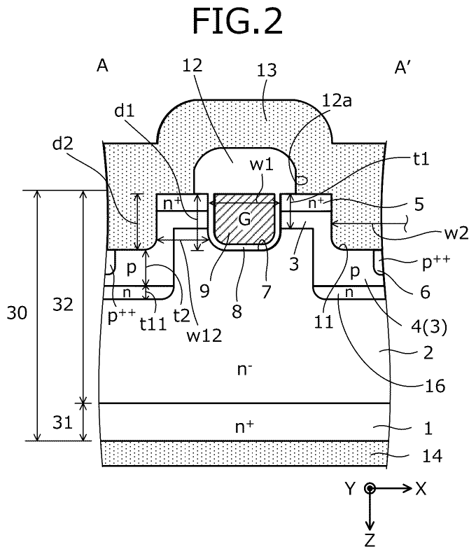

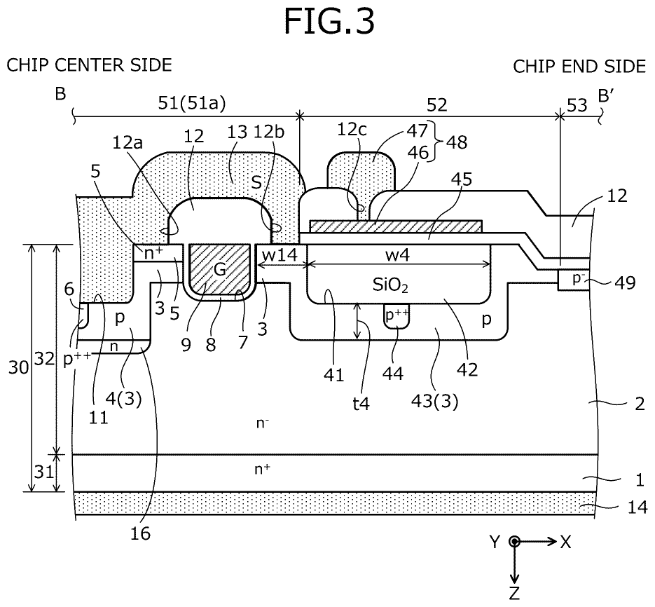

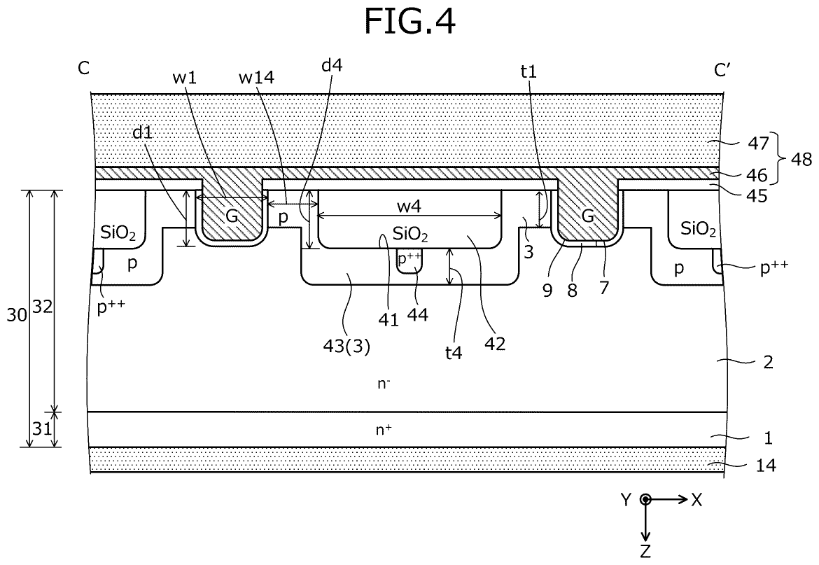

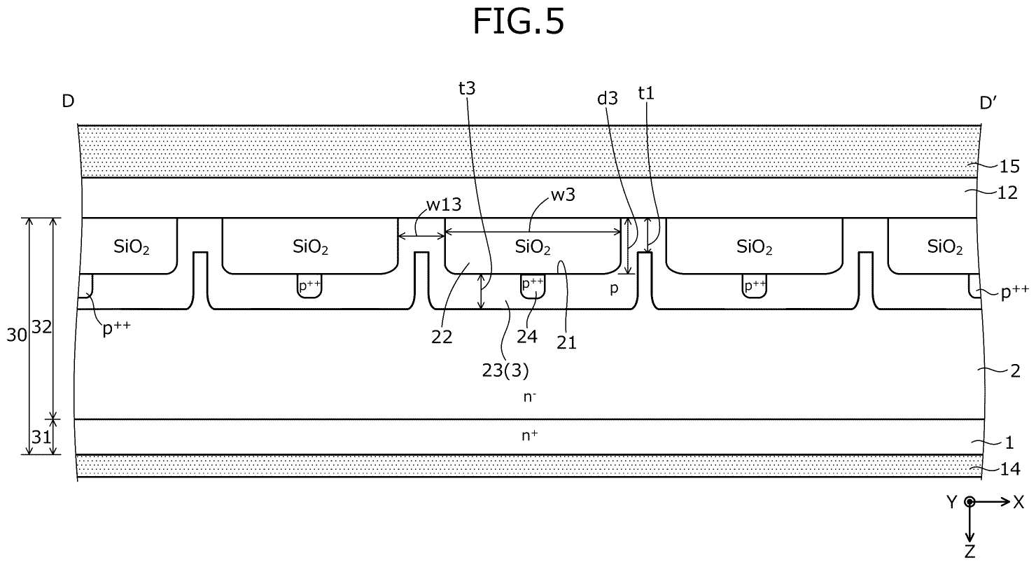

A structure of a silicon carbide semiconductor device according to a first embodiment is described. FIG. 1 is a plan view depicting a layout when the silicon carbide semiconductor device according to the first embodiment is viewed from a front side of a semiconductor substrate. FIGS. 2, 3, 4, and 5 are cross-sectional views depicting, respectively, the structure along cutting line A-A′, cutting line B-B′, cutting line C-C′, and cutting line D-D′ in FIG. 1. FIG. 2 depicts one unit cell (functional unit of a device) of an active region 51. FIGS. 3 and 4 depict the structure of an intermediate region 52. FIG. 5 depicts the structure directly beneath a gate pad 15 (side of the gate pad 15 facing an n⁺-type drain region 1).

FIGS. 1 to 5 depict the structure of the silicon carbide semiconductor device according to the first embodiment. A silicon carbide semiconductor device 10 according to the present embodiment depicted in FIG. 1 is a trench gate SiC-MOSFET with a double-trench source trench structure having in the active region 51, gate trenches (first trenches) 7 in which gate electrodes 9 are embedded and source trenches (second trenches) 11 in which a source electrode 13 is embedded, the gate trenches 7 and the source trenches 11 being provided in a semiconductor substrate (semiconductor chip) 30, at a front surface of the semiconductor substrate 30, which contains silicon carbide (SiC).

The active region 51 is a region through which a main current (drift current) passes in a direction orthogonal to a front surface of a semiconductor substrate 30 when the silicon carbide semiconductor device 10 is on. In the active region 51, the unit cells each having the same SiC-MOSFET structure are provided adjacent to one another. The active region 51, for example, has a substantially rectangular shape in a plan view and is provided in substantially a center (chip center) of the semiconductor substrate 30. In the active region 51, on the front surface of the semiconductor substrate 30, the source electrode 13 (first electrode, not depicted in FIG. 1, refer to FIGS. 2, 3) and the gate pad 15 are provided.

The source electrode 13 covers nearly an entire area of the front surface of the semiconductor substrate 30, in the active region 51. The source electrode 13, for example, has a substantially rectangular shape in which a portion is recessed inward (direction toward the chip center) in a plan view. The source electrode 13 also serves as a source pad (electrode pad). The gate pad 15, for example, has a substantially rectangular shape in a plan view (not depicted). The gate pad 15, for example, is provided near a border between the active region 51 and the intermediate region 52, the gate pad being provided in the recessed portion of the source electrode 13 so that three sides of the gate pad 15 face the source electrode 13.

An edge termination region 53 is a region between the active region 51 and an end (chip end) of the semiconductor substrate 30; the edge termination region 53 surrounds a periphery of the active region 51 in a substantially rectangular shape with the intermediate region 52 intervening therebetween. In FIG. 1, the border between the active region 51 and the intermediate region 52, and a border between the intermediate region 52 and the edge termination region 53 are indicated by dashed lines. The edge termination region 53 has a function of mitigating electric field of a front side of the semiconductor substrate 30 and sustaining a breakdown voltage. The breakdown voltage is a maximum voltage at which no damage or malfunction occurs in the silicon carbide semiconductor device 10 (SiC-MOSFET) at an operating voltage.

In the edge termination region 53, for example, a general voltage withstanding structure configured by multiple p-type regions surrounding the periphery of the active region 51 in concentric shapes, such as a field limiting ring (FLR), a junction termination extension (JTE), or a guard ring is disposed. For example, in FIG. 3, in a JTE structure in which multiple p-type regions are disposed in descending order of dopant concentration in a direction from the chip center to the chip end, a p-type region 49 that is innermost among the p-type regions is depicted.

In the intermediate region 52, which is between the active region 51 and the edge termination region 53, a gate runner 48 is provided on the front surface of the semiconductor substrate 30, via an insulating layer (a later-described field oxide film 45 and a later-described interlayer insulating film 12). The intermediate region 52 is a transition region in which a structure for electrically connecting a trench gate structure of the active region 51 and the voltage withstanding structure of the edge termination region 53 is disposed. The gate runner 48 surrounds the periphery of the active region 51 in a substantially rectangular shape. The gate runner 48 is connected to the gate pad 15.

The semiconductor substrate 30 is formed by growing, by epitaxy on a front surface of an n⁺-type starting substrate 31 containing silicon carbide, an epitaxial layer 32 of an n⁻-type, the epitaxial layer 32 constituting an n-type drift region (first semiconductor region) 2. The semiconductor substrate 30 has a first main surface having the epitaxial layer 32 as a front surface and a second main surface having the n⁺-type starting substrate 31 as a back surface. The n⁺-type starting substrate 31 constitutes the n⁺-type drain region 1. A portion of the epitaxial layer 32 excluding the p-type base region (second semiconductor region) 3, n⁺-type source regions (third semiconductor regions) 5, p⁺⁺-type contact regions 6, and n-type current spreading regions (fourth semiconductor regions) 16 constitutes the n⁻-type drift region 2.

The trench gate structure is configured by the p-type base region 3, the n⁺-type source regions 5, the p⁺⁺-type contact regions 6, the gate trenches 7, gate insulating films 8, and the gate electrodes 9 at the front side of the semiconductor substrate 30. The p-type base region 3, the n⁺-type source regions 5, the p⁺⁺-type contact regions 6, and the n-type current spreading regions 16 are diffused regions formed by ion implantation in the epitaxial layer 32. The p-type base region 3 is provided between the front surface of the semiconductor substrate 30 and the n⁻-type drift region 2, in the entire area of the active region.

The n⁺-type source regions 5 are provided between the front surface of the semiconductor substrate 30 and the p-type base region 3, spanning substantially an entire area of a region 51a directly beneath the source electrode 13, the n⁺-type source regions 5 being in contact with the p-type base region 3. The n⁺-type source regions 5, the p-type base region 3, and the n⁻-type drift region 2 are in contact with the gate insulating films 8 at sidewalls of the gate trenches 7. The n⁺-type source regions 5 are in ohmic contact with the source electrode 13 at the front surface of the semiconductor substrate 30 and sidewalls of the source trenches 11. The n⁺-type source regions 5 are not provided between the gate trenches 7 and later-described insulating trenches 21,41.

The p⁺⁺-type contact regions 6 are provided between bottoms of the source trenches 11 and later-described p-type deep base portions 4, the p⁺⁺-type contact regions 6 being in contact with the p-type deep base portions 4. The p⁺⁺-type contact regions 6 are in ohmic contact with the source electrode 13 at the bottoms of the source trenches 11. The p⁺⁺-type contact regions 6 are not provided between the front surface of the semiconductor substrate 30 and the p-type base region 3. The p⁺⁺-type contact regions 6 are not provided between the front surface of the semiconductor substrate 30 and the p-type base region 3, whereby formation of the trench gate structure is facilitated even when the cell pitch is narrow.

While it is preferable for the p⁺⁺-type contact regions 6 to be provided spanning an entire area of the bottoms of the source trenches 11, it suffices for ohmic contact portions in contact with the source electrode 13 to be formed at the bottoms of the source trenches 11 and the p⁺⁺-type contact regions 6 may be formed partially at the bottoms of the source trenches 11. The p⁺⁺-type contact regions 6 may be provided to a depth so as to not reach the n-type drift region 2 and may penetrate through the p-type deep base portions 4 in the depth direction and terminate in the n-type current spreading regions 16. The p⁺⁺-type contact regions 6 may be omitted.

The gate trenches 7 and the source trenches 11 are disposed to repeatedly alternate with one another in the first direction X parallel to the front surface of the semiconductor substrate 30. One unit cell is configured by a portion between a center of one of the source trenches 11 and a center of an adjacent one of the source trenches 11 in the first direction X with one of the gate trenches 7 intervening between the one and adjacent one of the source trenches 11. In one unit cell, two or more of the gate trenches 7 may be disposed adjacent to each other in the first direction X. In this instance, the source trenches 11 are disposed at a predetermined pitch in the first direction X, and between any adjacent two of the source trenches 11, the two or more of the gate trenches 7 are disposed at a predetermined pitch in the first direction X.

Further, two or more of the source trenches 11 may be disposed adjacent to each other in the first direction X in a single unit cell, provided the two or more the source trenches 11 do not exceed (in number) the number of the gate trenches 7 included in a single unit cell. In this instance, a portion between adjacent source trenches of the source trenches 11 sandwiching one or more of the gate trenches 7 and a portion between adjacent source trenches of the source trenches 11 not sandwiching any of the gate trenches 7 are disposed repeatedly alternating with one another in the first direction X. The portion between the adjacent source trenches of the source trenches 11 not sandwiching any of the gate trenches 7 is a non-operating region that does not function as the MOSFET.

As the number of the gate trenches 7 per unit cell increases, the number of channels (n-type inversion layers) formed (per unit cell) along the gate trenches 7 by the p-type base region 3 when the silicon carbide semiconductor device 10 is on increases and thus, the on-resistance decreases. On the other hand, as the number of the gate trenches 7 per unit cell increases, an effect of mitigating electric field near bottoms of the gate trenches 7 by the later-described p-type deep base portions 4 at the bottoms of the source trenches 11 decreases. Thus, preferably, the number of the gate trenches 7 per one unit cell may be about three, at maximum.

A width w1 of each of the gate trenches 7 in the first direction X may be less than a width w2 of each of the source trenches 11 in the first direction X. In this instance, when a depth d2 of each of the source trenches 11 is greater than a depth d1 of each of the gate trenches 7, manufacturing processes may be simplified by forming the source trenches 11 concurrently with the gate trenches 7. The width w1 of each of the gate trenches 7 in the first direction X and the width w2 of each of the source trenches 11 in the first direction X may be substantially a same width. Substantially the same width means the same width within a range that includes an allowable error due to manufacturing process variation.

The gate trenches 7 penetrate through the n⁺-type source regions 5 and the p-type base region 3 in the depth direction from the front surface of the semiconductor substrate 30 and terminate in the n-type drift region 2. Between the bottoms of the gate trenches 7 and the n⁺-type drain region 1, only the n-type drift region 2 is disposed, the bottoms of the gate trenches 7 are bordered by the n⁻-type drift region 2. Thus, as compared to an instance in which p-type regions for mitigating electric field are disposed at positions facing the bottoms of the gate trenches 7 in the depth direction, a width of a JFET portion in the first direction X increases and JFET resistance greatly decreases.

The JFET portion is a portion of the n-type drift region 2, between any one of the gate trenches 7 and an adjacent one of the later-described p-type deep base portions 4, the JFET portion being adjacent to a channel and constituting a current path of the drift current. The gate insulating films 8 are provided along inner walls (sidewalls and the bottoms) of the gate trenches 7. In the gate trenches 7, the gate electrodes 9 containing, for example, a polysilicon (poly-Si) is provided on the gate insulating films 8. Each of the gate trenches 7 and the source trenches 11 extends linearly (i.e., in a stripe-shape in an entire area of the active region 51) in a second direction Y, which is parallel to the front surface of the semiconductor substrate 30 and orthogonal to the first direction X.

While not depicted, the gate trenches 7 and the source trenches 11 may be disposed alternating with one another repeatedly in the first direction X and the gate trenches 7 and the source trenches 11 may be disposed alternating with one another repeatedly in the second direction Y. In this instance, the gate trenches 7 and the source trenches 11 have substantially rectangular shapes and appear scattered in a plan view (i.e., scattered in a matrix-like pattern in the entire area of the active region 51). Thus, unit cells are disposed adjacently in the first direction X and unit cells are disposed adjacently in the second direction Y.

The source trenches 11 penetrate through the n⁺-type source regions 5 in the depth direction from the front surface of the semiconductor substrate 30 and terminate at positions of substantially a same depth as the depth of the bottoms of the gate trenches 7 or a deep positions closer to the n⁺-type drain region 1 than are the bottoms of the gate trenches 7. Substantially the same depth means the same depth within a range that includes an allowable error (for example, within ±10%, preferably, within ±5%) due to manufacturing process variation. The greater is the depth d2 of the source trenches 11, the closer the later-described p-type deep base portions 4 at the bottoms of the source trenches 11 are formed to the n⁺-type drain region 1.

Preferably, the depth d2 of the source trenches 11 may be deeper than the depth d1 of the gate trenches 7. A reason for this is that SiC has a critical field strength that is one order of magnitude greater than a critical field strength of silicon (Si) and thus, is useful for, for example, high-voltage classes of 1200V or greater, and electric field applied to the gate insulating films 8 increases as compared to a Si-MOFET. The depth d2 of the source trenches 11 is made deeper than the depth d1 of the gate trenches 7, whereby electric field tends to concentrate at the bottoms of the source trenches 11 and thus, electric field applied to the gate insulating films 8 at the bottoms of the gate trenches 7 is mitigated.

Even when the depth d2 of the source trenches 11 is made deeper than the depth d1 of the gate trenches 7, an interval (mesa width) w12 between one of the gate trenches 7 and an adjacent one of the source trenches 11 is set suitably, whereby gate characteristics are not adversely affected. Further, the depth d2 of the source trenches 11 is greater than the depth d1 of the gate trenches 7, whereby as described hereinafter even when the source electrode 13 embedded in the source trenches 11 is positioned closer to the n⁺-type drain region 1 than are the gate electrodes 9 embedded in the gate trenches 7, the gate characteristics are not adversely affected.

The source electrode 13 is embedded in the source trenches 11. Between the n-type drift region 2 and the source trenches 11, the p-type base region 3 extends along inner walls of the source trenches 11. Along the inner walls (sidewalls and bottoms) of the source trenches 11, source contacts (electrical contact portions) electrically connecting the source electrode 13 with the p-type base region 3 and the p⁺⁺-type contact regions 6 are formed. Portions (hereinafter, the p-type deep base portions) 4 of the p-type base region 3 along the bottoms of the source trenches 11 border an entire area of the bottoms of the source trenches 11.

The p-type deep base portions 4 at the bottoms of the source trenches 11 form pn junctions with the later-described n-type current spreading regions 16, which are at deep positions closer to the n⁺-type drain region 1 than are the bottoms of the gate trenches 7, and the p-type deep base portions 4 mitigate electric field applied to the gate insulating films 8 at the bottoms of the gate trenches 7. Ion implantation of a p-type dopant for forming the p-type base region 3 at the bottoms of the source trenches 11 is performed, whereby the p-type deep base portions 4 may be formed without variations in doping concentration, at deeper positions closer to the n⁺-type drain region 1 than are the bottoms of the gate trenches 7.

For example, in an instance in which p-type regions terminating at deep positions toward the n⁺-type drain region 1 are formed without providing the source trenches 11 between adjacent trenches of the gate trenches 7, doping concentration of the p-type regions may vary and crystal defects may occur in the semiconductor substrate 30 due to the ion implantation of a p-type dopant from the front surface of the semiconductor substrate 30 by a high acceleration energy. Further, in an instance in which the p-type regions are formed by growing the epitaxial layer 32 in multiple stages of epitaxy and repeatedly performing ion implantation of a p-type dopant for each stage of epitaxy, a problem arises in that the number of processes increases.

On the other hand, in the present embodiment, the ion implantation of a p-type dopant for forming the p-type base region 3 is further performed at the inner walls of the source trenches 11. The p-type base region 3 is formed in a surface region of the semiconductor substrate 30, at the front surface of the semiconductor substrate 30 in the active region 51 and the intermediate region 52 and in an entire area at the surface of the inner walls of the source trenches 11; and portions of the p-type base region 3 along the bottoms of the source trenches 11 constitute the p-type deep base portions 4. Thus, ion implantation by a high acceleration energy and processes of growing the epitaxial layer 32 in multiple epitaxy stages are unnecessary.

Further, the deeper the p-type deep base portions 4 at the bottoms of the source trenches 11 are disposed toward the n⁺-type drain region 1, the higher is the effect of mitigating electric field near the bottoms of the gate trenches 7 by the p-type deep base portions 4. Further, the p-type deep base portions 4 constitute resistance components when a large current (short-circuit current) exceeding a rated-current flows between a drain and source of the SiC-MOSFET (the silicon carbide semiconductor device 10) during load short-circuit or alarm short-circuit and thus the deeper are the p-type deep base portions 4 at the bottoms of the source trenches 11, the greater the short-circuit capability is enhanced.

A thickness (thickness of a portion of the p-type base region 3, between the n-type drift region 2 and the bottom of any one of the source trenches 11) t2 of each of the p-type deep base portions 4 may be greater than a thickness t1 of a portion of the p-type base region 3 in a mesa region (portion of the p-type base region 3, between the front surface of the semiconductor substrate 30 and the n⁻-type drift region 2). In the p-type base region 3, to make the thickness t2 of the p-type deep base portions 4 relatively thicker, a p-type dopant may be further ion-implanted at the bottoms of the source trenches 11 during formation of the p-type base region 3. For example, in the p-type base region 3, the thickness t2 of the p-type deep base portions 4 may also be made relatively thicker by performing the ion implantation of a p-type dopant for forming the p⁺⁺-type contact regions 6 at the bottoms of the source trenches 11.

The n-type current spreading regions 16 are provided opposing, in the depth direction, lower surfaces (surfaces facing the n⁺-type drain region 1) of the p-type deep base portions 4, the n-type current spreading regions 16 being provided only between the n-type drift region 2 and the p-type deep base portions 4, in contact with the n-type drift region 2. Each of the n-type current spreading regions 16 is in contact with an entire lower surface of a corresponding one of the p-type deep base portions 4 and borders an entire area of the lower surface of the corresponding one of the p-type deep base portions 4. The n-type current spreading regions 16 constitute a so-called current spreading layer (CSL) that reduces carrier spreading resistance. Further, the n-type current spreading regions 16 have a function of facilitating avalanche breakdown near the bottoms of the source trenches 11 when the SiC-MOSFET is off and lowering the breakdown voltage (breakdown voltage between the drain and source).

The n-type current spreading regions 16 may facilitate avalanche breakdown near the bottoms of the source trenches 11 when the SiC-MOSFET is off and may be provided apart from the p-type deep base portions 4, at positions facing the p-type deep base portions 4 in the depth direction. While, preferably, the n-type current spreading regions 16 may face the entire area of the bottoms of the p-type deep base portions 4 in the depth direction, the n-type current spreading regions 16 have the described function when facing only a part of each of the lower surfaces of the p-type deep base portions 4. The n-type current spreading regions 16, for example, are formed by ion implantation of an n-type dopant at the bottoms of the source trenches 11 after formation of the source trenches 11 but before formation of the p-type deep base portions 4. The n-type current spreading regions 16 may be formed using a mask for forming the source trenches 11.

For example, to increase the thickness t2 of the p-type deep base portions 4, a mask used when a p-type dopant is ion-implanted at the bottoms of the source trenches 11 may be used to form the n-type current spreading regions 16. The n-type current spreading regions 16 are formed at deeper positions closer to the n⁺-type drain region 1 than are the p-type deep base portions 4 by ion implantation by an acceleration energy higher than the acceleration energy for forming the p-type deep base portions 4 and thus, the n-type current spreading regions 16 diffuse relatively easily in directions parallel to the front surface of the semiconductor substrate 30. Thus, the p-type deep base portions 4 and the n-type current spreading regions 16 are formed by self-alignment, whereby the n-type current spreading regions 16 may be formed spanning the entire area of the lower surfaces of the p-type deep base portions 4 and a width of each of the n-type current spreading regions 16 may made to be a same as a width of each of the p-type deep base portions 4.

The intermediate region 52, the edge termination region 53, and a region 51b directly beneath the gate pad 15 are free of the n-type current spreading regions 16. As a result, when the SiC-MOSFET is off, avalanche breakdown may be intentionally caused to occur only directly beneath the source trenches 11 in the region 51a directly beneath the source electrode 13; avalanche breakdown does not occur in the edge termination region 53, the intermediate region 52, or the region 51b directly beneath the gate pad 15; and thus, the breakdown voltage of the intermediate region 52 and the edge termination region 53 may be made higher than the breakdown voltage of the active region 51 and an overall breakdown voltage of the silicon carbide semiconductor device 10 (the semiconductor substrate 30) may be determined by the breakdown voltage of the active region 51.

In the active region 51, trenches (hereinafter, insulating trenches) 21 embedded with an embedded insulating layer 22 are provided in the region 51b directly beneath the gate pad 15. Between the insulating trenches 21 and the n-type drift region 2, the p-type base region 3 extends along inner walls of the insulating trenches 21 from the active region 51 and borders an entire area of the bottoms of the insulating trenches 21. Lower surfaces of portions (hereinafter, p-type deep base portions) 23 of the p-type base region 3 along the bottoms of the insulating trenches 21 are in contact with the n-type drift region 2 and are bordered by the n⁻-type drift region 2. Each of the insulating trenches 21, for example, extends in in a stripe-shape in the second direction Y. A width w3 of each of the insulating trenches 21 in the first direction X and an interval w13 between any adjacent two of the insulating trenches 21 may be suitably set.

A portion of the p-type base region 3 directly beneath the gate pad 15 has a function of suppressing rises of the potential of the region 51b directly beneath the gate pad 15 due to a steep rise of the voltage applied to a drain electrode 14. The insulating trenches 21 are disposed in the region 51b directly beneath the gate pad 15, whereby p-type deep base portions 23 at the bottoms of the insulating trenches 21 are formed at deep positions toward the n⁺-type drain region 1. A thickness t3 of each of the p-type deep base portions 23, for example, is substantially a same as the thickness t2 of the p-type deep base portions 4 at the bottoms of the source trenches 11. A depth d3 of each of the insulating trenches 21 is substantially a same as the depth d2 of the source trenches 11, whereby the p-type deep base portions 23 may be formed at positions of a depth that is substantially a same as the depth of the p-type deep base portions 4 at the bottoms of the source trenches 11.

The p-type deep base portions 23 at the bottoms of the insulating trenches 21 that are adjacent to each other are continuous, whereby in an entire area of the region 51b directly beneath the gate pad 15, a lower surface of the p-type base region 3 may be substantially flat and at a deep position closer to the n⁺-type drain region 1 than are the bottoms of the insulating trenches 21. The region 51b directly beneath the gate pad 15 is a region facing an entire area of the surface of the gate pad 15 and, in a plan view, has a substantially rectangular shape with dimensions substantially a same as the dimensions of the gate pad 15 or dimensions slightly larger than the dimensions of the gate pad 15. Between the bottoms of the insulating trenches 21 and the p-type deep base portions 23, p⁺⁺-type contact regions 24 may be provided in contact with the p-type deep base portions 23, similar to the p⁺⁺-type contact regions 6 at the bottoms of the source trenches 11.

The interlayer insulating film 12 is provided in an entire area of the front surface of the semiconductor substrate 30 and covers the gate electrodes 9. Multiple contact holes 12a, 12b, 12c penetrating through the interlayer insulating film 12 in the depth direction Z are provided. In the contact holes 12a, the source trenches 11 and the n⁺-type source regions 5 are exposed. In each of the contact holes 12b, a portion of the p-type base region 3 between one of the gate trenches 7 and an adjacent one of the insulating trenches 21, 41 is exposed. In the contact hole 12c, a later-described gate polysilicon wiring layer 46 of the intermediate region 52 is exposed. The source electrode 13 is embedded in the source trenches 11 via the contact holes 12a of the interlayer insulating film 12 and is in contact with the p-type base region 3, the n⁺-type source regions 5, and the p⁺⁺-type contact regions 6, at the inner walls of the source trenches 11.

On a portion of the interlayer insulating film 12 in the active region 51, the gate pad 15 is provided. The source electrode 13 and the gate pad 15 are metal electrode layers provided at a same level and are electrically insulated from each other by the interlayer insulating film 12. The gate pad 15 faces the insulating trenches 21, the embedded insulating layer 22, and the p-type deep base portions 23 with the interlayer insulating film 12 therebetween. All the gate electrodes 9 are electrically connected to the gate pad 15 via the gate runner 48. The drain electrode (second electrode) 14 is provided in an entire area of the back surface (back surface of the n⁺-type starting substrate 31) of the semiconductor substrate 30. The drain electrode 14 is in ohmic contact with the back surface of the semiconductor substrate 30 and is electrically connected to the n⁺-type drain region 1 (the n⁺-type starting substrate 31).

In the intermediate region 52, the gate trenches 7 extending therein from the active region 51 and the insulating trenches 41 in which the embedded insulating layer 42 is embedded are provided. Between the n⁻-type drift region 2 and the insulating trenches 41, the p-type base region 3 extends along inner walls of the insulating trenches 41 from the active region 51 and borders an entire area of bottoms of the insulating trenches 41. Lower surfaces of portions (hereinafter, p-type deep base portions) 43 of the p-type base region 3 along the bottoms of the insulating trenches 41 are in contact with the n-type drift region 2 and are bordered by the n-type drift region 2. Each of the insulating trenches 41, for example, extends in a stripe-shape in the second direction Y. A width w4 of each of the insulating trenches 41 in the first direction X and an interval w14 between one of the gate trenches 7 and an adjacent one of the insulating trenches 41 may be suitably set.

For example, the width w4 of the insulating trenches 41 in the first direction X is substantially a same as the width w2 of each of the source trenches 11 in the first direction X. The intermediate region 52 surrounds the periphery of the active region 51 in substantially a rectangular shape, and at opposite sides of the intermediate region (the sides parallel to the first direction X), the insulating trenches 41 are provided facing the source trenches 11 in the second direction Y and are dispersed so that one of the gate trenches 7 is between any adjacent two of the source trenches 11 in the first direction X (FIG. 4). On the other hand, at opposite sides of the intermediate region 52 (the sides parallel to the second direction Y), each of the insulating trenches 41 extends linearly (or in a stripe-shape) in the second direction Y, spanning an entire area of the opposite sides (FIG. 5). At the opposite sides of the intermediate region 52, parallel to the second direction Y, an entire area of each of the insulating trenches 41 faces, in the depth direction Z, opposite sides of the gate runner 48 (the sides parallel to the second direction Y).

The insulating trenches 41 are disposed in the intermediate region 52, whereby the p-type deep base portions 43 at the bottoms of the insulating trenches 41 are formed at deep positions toward the n⁺-type drain region 1. A thickness t4 of each of the p-type deep base portions 43, for example, is a same as the thickness t2 of the p-type deep base portions 4 at the bottoms of the source trenches 11. A depth d4 of the insulating trenches 41 is substantially a same as the depth d2 of the source trenches 11, whereby the p-type deep base portions 43 may be formed at positions of a depth substantially a same as the depth of the p-type deep base portions 4 at the bottoms of the source trenches 11. Between the bottoms of the insulating trenches 41 and the p-type deep base portions 43, p⁺⁺-type contact regions 44 may be provided in contact with the p-type deep base portions 43, similar to the p⁺⁺-type contact regions 6 at the bottoms of the source trenches 11.

In the intermediate region 52, the p-type base region 3 surrounds the periphery of the active region 51 in a substantially rectangular shape, along the border between the active region 51 and the intermediate region 52. A portion of the p-type base region 3 in the intermediate region 52 has a function of making electric field of the front surface of the semiconductor substrate 30 in the intermediate region 52 uniform. In the intermediate region 52 and the edge termination region 53, the field oxide film 45 is provided between the front surface of the semiconductor substrate 30 and the interlayer insulating film 12. The field oxide film 45 may extend between the interlayer insulating film 12 and the front surface of the semiconductor substrate 30 in the active region 51 so as to face the entire surface of the gate pad 15. In the intermediate region 52, the gate polysilicon wiring layer 46 is provided between the field oxide film 45 and the interlayer insulating film 12. The embedded insulating layers 22, 42 may be formed concurrently with the field oxide film 45.

The gate electrodes 9 are connected to the gate polysilicon wiring layer 46 at longitudinal ends (ends in the second direction Y) of the gate trenches 7. On the gate polysilicon wiring layer 46, a gate metal wiring layer 47 is provided via the contact hole 12c of the interlayer insulating film 12. The gate metal wiring layer 47 is connected to the gate pad 15. The gate polysilicon wiring layer 46 and the gate metal wiring layer 47 surround the periphery of the active region 51 and configure the gate runner 48. The gate runner 48 faces the p-type base region 3, the p-type deep base portions 43, the insulating trenches 41, and the embedded insulating layer 42, via an insulating layer (the field oxide film 45 and the interlayer insulating film 12).

Operation of the silicon carbide semiconductor device 10 (SiC-MOSFET) according to the first embodiment is described. Voltage that is positive with respect to the source electrode 13 is applied to the drain electrode 14 (forward bias between the drain and source), whereby pn junctions (main junctions) between the p⁺⁺-type contact regions 6, the p-type base region 3, the n-type current spreading regions 16, the n⁻-type drift region 2, and the n⁺-type drain region 1 are reverse biased. In this state, when voltage applied to the gate electrodes 9 is less than a gate threshold voltage, the SiC-MOSFET maintains an off-state.

As described, the main junctions are reverse biased, whereby the p-type deep base portions 4 (or the n-type current spreading regions 16, or both) are depleted. Thus, the interval w12 between one of the gate trenches 7 and an adjacent one of the source trenches 11 is suitably set, whereby electric field applied to the gate insulating films 8 at the bottoms of the gate trenches 7 may be mitigated by the p-type deep base portions 4 at the bottoms of the source trenches 11 without providing p-type regions for mitigating electric field at the bottoms of the gate trenches 7.

Further, the n-type current spreading regions 16 are provided opposing, in the depth direction, the p-type deep base portions 4 at the bottoms of the source trenches 11, whereby when the SiC-MOSFET is off, electric field may be caused to concentrate near the bottoms of the source trenches 11. As a result, when the SiC-MOSFET is off, avalanche breakdown may be intentionally caused to occur near the bottoms of the source trenches 11 and the breakdown voltage may be reduced, thereby enabling reduction of electric field strength near the bottoms of the gate trenches 7.

On the other hand, when voltage that is positive with respect to the source electrode 13 is applied to the drain electrode 14 and voltage at least equal to a gate threshold voltage is applied to the gate electrodes 9, in portions of the p-type base region 3 along the sidewalls of the gate trenches 7, channels (n-type inversion layers) are formed. As a result, the drift current (main current) flows from the n⁺-type drain region 1, through the n⁻-type drift region 2, the JFET portion (portion between one of the gate trenches 7 and an adjacent one of the p-type deep base portions 4), and the channels, to the n⁺-type source regions 5, and the SiC-MOSFET turns on.

The n-type current spreading regions 16 are provided facing the p-type deep base portions 4 at the bottoms of the source trenches 11 in the depth direction, whereby the n-type doping concentration near lower surfaces of the p-type deep base portions 4 is high. Thus, from the reverse biased main junctions (pn junctions), spreading of a depletion layer in the n-type drift region 2 is inhibited. As a result, when the SiC-MOSFET is on, narrowing of the path of the drift current flowing through the n-type drift region 2 due to the depletion layer spreading from the main junctions may be suppressed and increases in the JFET resistance may be suppressed.

Further, as described, even when the interval w12 between one of the gate trenches 7 and an adjacent one of the source trenches 11 is increased by an amount equivalent to the amount that the electric field strength near the bottoms of the gate trenches 7 is reduced, the effect of mitigating electric field near the bottoms of the gate trenches 7 by the p-type deep base portions 4 at the bottoms of the source trenches 11 is obtained. Thus, by increasing the interval w12 between one of the gate trenches 7 and an adjacent one of the source trenches 11 and increasing a width of the JFET portion in the first direction X, the JFET resistance may be reduced.

As described, according to the first embodiment, the n-type current spreading regions are provided opposing, in the depth direction, the p-type deep base portions at the bottoms of the source trenches, whereby when the SiC-MOSFET is off, avalanche breakdown may be intentionally caused to occur near the bottoms of the source trenches. As a result, the breakdown voltage may be reduced and the electric field strength near the bottoms of the gate trenches may be reduced and thus, by increasing the interval between one of the gate trenches and an adjacent one of the source trenches and increasing the width of the JFET portion in the first direction X, the JFET resistance and the on-resistance may be reduced.

Further, according to the first embodiment, p-type regions for mitigating electric field are not disposed at positions facing the bottoms of gate trenches in the depth direction, whereby the width of the JFET portion increases and the JFET resistance is greatly reduced. Further, electric field applied to the gate insulating films at the bottoms of the gate trenches may be mitigated by the p-type deep base portions at the bottoms of the source trenches without disposing, at positions facing the bottoms of the gate trenches in the depth direction, p-type regions for mitigating the electric field. Further, according to the first embodiment, as described, the electric field strength near the bottoms of the gate trenches may be reduced and thus, as compared to the conventional structure, which is free of the n-type current spreading regions (refer to FIG. 9), the effect of mitigating electric field near the bottoms of the gate trenches is increased and reliability may be enhanced.

Further, according to the first embodiment, the n-type current spreading regions are provided facing the p-type deep base portions at the bottoms of the source trenches in the depth direction, whereby the n-type doping concentration near the lower surfaces of the p-type deep base portions increases. As a result, spreading of a depletion layer in the n-type drift region from the reverse biased pn junctions between the p-type deep base portions, the n-type current spreading regions, and the n⁻-type drift region is inhibited. As a result, when the SiC-MOSFET is in the on-state, narrowing of the path of the drift current flowing through the n-type drift region may be suppressed and thus, increases in the JFET resistance may be suppressed, the narrowing of the path of the drift current being due to the depletion layer spreading from the pn junctions between the p-type deep base portions, the n-type current spreading regions, and the n-type drift region.

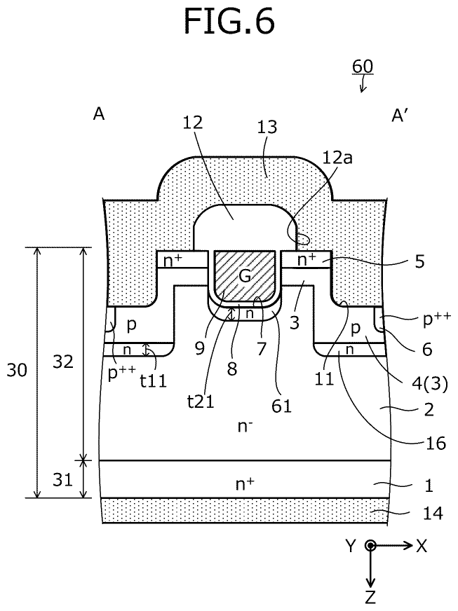

A structure of a silicon carbide semiconductor device according to a second embodiment is described. FIG. 6 is a cross-sectional view depicting the structure of the silicon carbide semiconductor device according to the second embodiment. A layout when a silicon carbide semiconductor device 60 according to the second embodiment is viewed from the front surface of the semiconductor substrate 30 is a same as the layout in the first embodiment (refer to FIG. 1). FIG. 6 corresponds to a cross-section of the structure along cutting line A-A′ in FIG. 1. The silicon carbide semiconductor device 60 according to the second embodiment differs from the silicon carbide semiconductor device 10 according to the first embodiment (refer to FIGS. 1 to 5) in that in addition to the n-type current spreading regions 16 directly beneath the source trenches, n-type current spreading regions (fifth semiconductor regions) 61 in contact with the n⁻-type drift region 2 are provided at positions facing the bottoms of the gate trenches 7 in the depth direction.

The n-type current spreading regions 61 have a function of increasing the n-type doping concentration near the JFET portions and lowering the JFET resistance. The n-type current spreading regions 61 may face an entire area of the bottoms of the gate trenches 7 or may face only a part of each of the bottoms of the gate trenches 7. The n-type current spreading regions 61 may be in contact with the gate insulating films 8 at the bottoms of the gate trenches 7 or may be provided to be apart from the bottoms of the gate trenches 7. The region 51b directly beneath the gate pad 15 and the intermediate region 52 are free of the n-type current spreading regions 61.

A thickness t21 of each of the n-type current spreading regions 61 may be substantially a same as the thickness t11 of the n-type current spreading regions 16. Substantially the same thickness means the same thickness within a range that includes an allowable error, for example, within ±5%, due to manufacturing process variation. A doping concentration of the n-type current spreading regions 61 is not more than a doping concentration of the n-type current spreading regions 16 directly beneath the source trenches. The n-type current spreading regions 61, for example, are formed after the gate trenches 7, by ion implantation of an n-type dopant at the bottoms of the gate trenches 7.

As described, according to the second embodiment, effects similar to those of the first embodiment may be obtained. Further, according to the second embodiment, the n-type current spreading regions are provided facing the bottoms of the gate trenches in the depth direction, whereby the on-resistance may be further reduced.

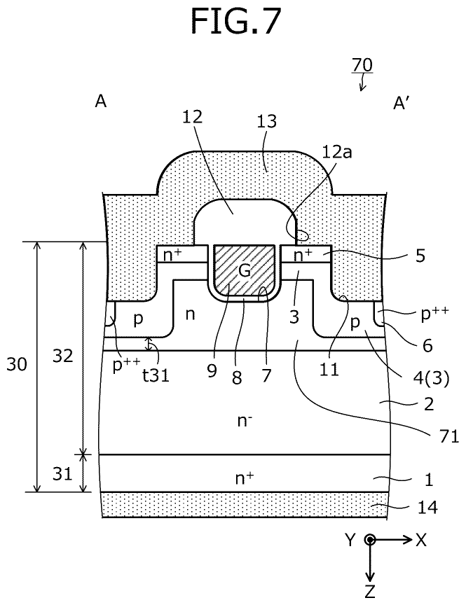

A structure of a silicon carbide semiconductor device according to a third embodiment is described. FIG. 7 is a cross-sectional view depicting the structure of the silicon carbide semiconductor device according to the third embodiment. A layout when a silicon carbide semiconductor device 70 according to the third embodiment is viewed from the front surface of the semiconductor substrate 30 is a same as the layout in the first embodiment (refer to FIG. 1). FIG. 7 corresponds to a cross-section of the structure along cutting line A-A′ in FIG. 1. The silicon carbide semiconductor device 70 according to the third embodiment differs from the silicon carbide semiconductor device 10 according to the first embodiment (refer to FIGS. 1 to 5) in that not only directly beneath the source trenches 11 but in an entire area between the p-type base region 3 and the n⁻-type drift region 2, an n-type current spreading region (fourth semiconductor region) 71 is provided in contact with said regions.

The n-type current spreading region 71 has a function of increasing the n-type doping concentration of the JFET portions and lowering the JFET resistance. The n-type current spreading region 71 is provided between the p-type base region 3 and the n⁻-type drift region 2, spanning directly beneath the source trenches 11 and the gate trenches 7. The n-type current spreading region 71 is in contact with an entire area of the p-type base region 3 (including the p-type deep base portions 4), borders the p-type base region 3, and in an entire area at the bottoms of the gate trenches 7, is in contact with the gate insulating films 8 and borders the bottoms of the gate trenches 7. The n-type current spreading region 71 is in contact with the gate insulating films 8 at the bottoms of the gate trenches 7. A lower surface of the n-type current spreading region 71, for example, is a flat surface parallel to the front surface of the semiconductor substrate 30.

The intermediate region 52, the edge termination region 53, and the region 51b directly beneath the gate pad 15 are free of the n-type current spreading region 71. A thickness 31 of each portion of the n-type current spreading region 71 directly beneath the source trenches 11 may be set to be substantially a same as the thickness t11 of the n-type current spreading regions 16 in the first embodiment (refer to FIG. 2). In the n-type current spreading region 71, a portion thereof between any one of the gate trenches 7 and an adjacent one of the p-type deep base portions 4 constitutes the JFET portion. The n-type current spreading region 71, for example, is formed before the gate trenches 7 and the source trenches 11, by ion implantation of an n-type dopant in the epitaxial layer 32.

As described, according to the third embodiment, effects similar to those of the first and second embodiments may be obtained. Further, according to the third embodiment, the n-type current spreading region is provided in a region between the p-type base regions and the n-type drift region, whereby effects similar to effects of the second embodiment may be obtained.

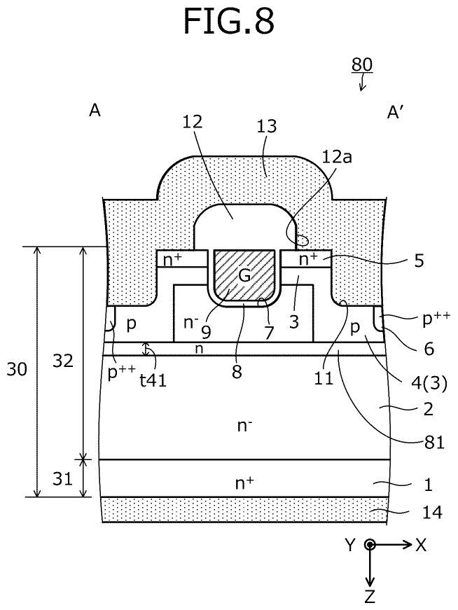

A structure of a silicon carbide semiconductor device according to a fourth embodiment is described. FIG. 8 is a cross-sectional view of the structure of the silicon carbide semiconductor device according to the fourth embodiment. A layout when a silicon carbide semiconductor device 80 according to the fourth embodiment is viewed from the front surface of the semiconductor substrate 30 is a same as the layout in the first embodiment (refer to FIG. 1). FIG. 8 corresponds to a cross-section of the structure along cutting line A-A′ in FIG. 1. The silicon carbide semiconductor device 80 according to the fourth embodiment differs from the silicon carbide semiconductor device 10 according to the first embodiment (refer to FIGS. 1 to 5) in that an n-type current spreading region (fourth semiconductor region) 81 extends having substantially a constant thickness t41, spanning directly beneath the source trenches 11 and the gate trenches 7.

The n-type current spreading region 81 has a function of increasing the n-type doping concentration of the JFET portions and lowering the JFET resistance. The n-type current spreading region 81 is provided in the region 51a directly beneath the source electrode 13, between the p-type base region 3 and the n⁻-type drift region 2, spanning portions directly beneath the source trenches 11 and portions directly beneath the gate trenches 7. The n-type current spreading region 81 faces an entire area of the p-type base region 3 (including the p-type deep base portions 4) in the depth direction and an entire area of the bottoms of the gate trenches 7 in the depth direction.

The n-type current spreading region 81, directly beneath the source trenches 11, may be in contact with the p-type base region 3 (i.e., the p-type deep base portions 4) or may be disposed apart from the p-type base region 3 in the depth direction. Between any one of the gate trenches 7 and an adjacent one of the p-type deep base portions 4, the n-type current spreading region 81 is disposed apart from the p-type base region 3 in the depth direction. The n-type current spreading region 81 is provided apart from the bottoms of the gate trenches 7 in the depth direction. The n⁻-type drift region 2 is between the n-type current spreading region 81 and the gate trenches 7. The bottoms of the gate trenches 7, similar to the first embodiment, are bordered by the n-type drift region 2.

The thickness t41 of the n-type current spreading region 81 is uniform, an upper surface (surface facing the n⁺-type source regions) and a lower surface of the n-type current spreading region 81 being flat surfaces parallel to the front surface of the semiconductor substrate 30. The thickness t41 of the n-type current spreading region 81 may be substantially a same as the thickness t11 of the n-type current spreading regions 16 (refer to FIG. 2) in the first embodiment. The n-type current spreading region 81, for example, is formed before the gate trenches 7 and the source trenches 11, by ion implantation of an n-type dopant in the epitaxial layer 32.

As described, according to the fourth embodiment, effects similar to those of the first to third embodiments may be obtained. Further, according to the fourth embodiment, the bottoms of the gate trenches 7 are bordered by the n-type drift region 2, whereby the electric field strength near the bottoms of the gate trenches 7 may be reduced.

The present invention described above is not limited to the embodiments described and various modifications within a range not departing from the spirit of the invention are possible. Further, in the embodiments described above, while a first conductivity type is assumed to be an n-type and a second conductivity type is assumed to be a p-type, the present invention is similarly implemented when the first conductivity type is a p-type and the second conductivity type is an n-type.

According to the present invention described above, electric field may be caused to concentrate near the bottoms of the second trenches and thus, avalanche current may be intentionally caused to occur at the bottoms of the second trenches. As a result, the breakdown voltage may be reduced and thus, electric field strength near the bottom of the first trench may be decreased. Thus, the interval between one of the first trenches and an adjacent one of the second trenches is increased and the width of the JFET portion in the first direction increased, whereby the JFET resistance may be reduced.

A silicon carbide semiconductor device according to the present invention is a trench gate silicon carbide semiconductor device having a source trench and achieves an effect in that on-resistance may be reduced.

As described, the silicon carbide semiconductor device according to the present invention is useful for power semiconductors used in power converting equipment, power source devices of various types of industrial machines, etc. and is particularly suitable for 1200V class or higher SiC-MOSFETs.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface opposite to each other;
a first semiconductor region of a first conductivity type, provided in the semiconductor substrate;
a second semiconductor region of a second conductivity type, provided in the semiconductor substrate between the first main surface of the semiconductor substrate and the first semiconductor region;
a third semiconductor region of the first conductivity type, selectively provided in the semiconductor substrate between the first main surface of the semiconductor substrate and the second semiconductor region;
a first trench penetrating through the third semiconductor region and the second semiconductor region in a depth direction and terminating in the first semiconductor region;
a gate electrode provided in the first trench, via a gate insulating film;
a plurality of second trenches penetrating through the third semiconductor region in the depth direction and terminating in the second semiconductor region, at a depth at least equal to a depth of the first trench, the plurality of second trenches being provided apart from the first trench and a periphery of each of the plurality of second trenches being bordered by the second semiconductor region in a plan view of the silicon carbide semiconductor device;
a fourth semiconductor region of the first conductivity type, provided opposing, in the depth direction, a portion of the second semiconductor region that is below a bottom of each of the plurality of second trenches, the fourth semiconductor region having a doping concentration higher than a doping concentration of the first semiconductor region;
a first electrode provided at the first main surface of the semiconductor substrate, embedded in the plurality of second trenches, the first electrode being in contact with the second semiconductor region and the third semiconductor region at an inner wall of each of the plurality of second trenches; and
a second electrode provided at the second main surface of the semiconductor substrate.

2. The silicon carbide semiconductor device according to claim 1, further comprising a fifth semiconductor region of the first conductivity type, provided opposing, in the depth direction, a bottom of the first trench, the fifth semiconductor region having a doping concentration higher than the doping concentration of the first semiconductor region.

3. The silicon carbide semiconductor device according to claim 2, wherein the doping concentration of the fifth semiconductor region is not more than the doping concentration of the fourth semiconductor region.

4. The silicon carbide semiconductor device according to claim 1, wherein
the fourth semiconductor region is provided spanning an entire area between the second semiconductor region and the first semiconductor region, and
the fourth semiconductor region further opposes, in the depth direction, a bottom of the first trench.

5. The silicon carbide semiconductor device according to claim 4, wherein the fourth semiconductor region is in contact with the gate insulating film, at the bottom of the first trench.

6. The silicon carbide semiconductor device according to claim 4, wherein the fourth semiconductor region is apart from the bottom of the first trench.

7. The silicon carbide semiconductor device according to claim 6, wherein a thickness of the fourth semiconductor region is constant over a portion thereof facing the bottom of the first trench and bottoms of the plurality of second trenches.

8. The silicon carbide semiconductor device according to claim 1, wherein the fourth semiconductor region is in contact with said portion of the second semiconductor region.

9. The silicon carbide semiconductor device according to claim 1, wherein a bottom of the first trench is bordered by the first semiconductor region.

10. The silicon carbide semiconductor device according to claim 1, wherein
the plurality of second trenches is disposed with a predetermined interval in a direction parallel to the first main surface of the semiconductor substrate, and
the first trench is disposed in plural at a predetermined pitch in the direction, each between adjacent two of the plurality of second trenches.

11. The silicon carbide semiconductor device according to claim 1, further comprising a plurality of first trenches that each is said first trench, wherein
the plurality of first trenches and the plurality of second trenches are so arranged that each of the plurality of second trenches has, respectively on two sides thereof,
one of the plurality of first trenches, provided separately from said each second trench, and
another one of the plurality of second trenches, provided separately from said each second trench.
